(19) United States
(12) Patent Application Publication
(10) Pub. No.: US 2019/0296188 A1
(43) Pub. Date: Sep. 26, 2019

(54) MICRO LIGHT-EMITTING DIODE CHIP

(71) Applicant: PlayNitride Display Co., Ltd., MiaoLi County (TW)

(72) Inventors: Yu-Hung Lai, MiaoLi County (TW); Yu-Yun Lo, MiaoLi County (TW); Tzu-Yang Lin, MiaoLi County (TW); Yun-Li Li, MiaoLi County (TW)

(73) Assignee: PlayNitride Display Co., Ltd., MiaoLi County (TW)

(21) Appl. No.: 16/438,483

(22) Filed: Jun. 12, 2019

Related U.S. Application Data
(63) Continuation-in-part of application No. 15/866,473, filed on Jan. 10, 2018.

(30) Foreign Application Priority Data
Jan. 10, 2017 (TW) 106100760

(51) Int. Cl. H01L 33/08; H01L 33/06; H01L 33/32; H01L 33/38; H01L 33/40; H01L 33/44

(52) U.S. Cl. CPC H01L 33/08; H01L 33/06; H01L 33/44; H01L 33/382; H01L 33/405; H01L 33/32

(57) ABSTRACT

A μLED chip having at least two light-emitting regions and including an epitaxial structure layer, a first-type electrode and at least two second-type electrodes is provided. The epitaxial structure layer includes a first-type semiconductor layer, at least two light-emitting layers and at least two second-type semiconductor layers. The light-emitting layers are respectively located in the light-emitting regions, one of the light-emitting layers has a first area, and the other light-emitting layer has a second area. A ratio of the first area to the second area is between 1.5 and 3, and a difference in current densities respectively passing through the at least two light-emitting regions is less than 10%. The light-emitting layers are located between the first-type semiconductor layer and the second-type semiconductor layers. The first-type electrode is electrically connected to the first-type semiconductor layer. The second-type electrodes are electrically connected to the second-type semiconductor layer, respectively.

### CROSS-REFERENCE TO RELATED APPLICATION

This application is a continuation-in-part application of and claims the priority benefit of U.S. application Ser. No. 15/866,473, filed on Jan. 10, 2018, now pending, which claims the priority benefit of Taiwan application serial no. 106100760, filed on Jan. 10, 2017. The entirety of each of the above-mentioned patent applications is hereby incorporated by reference herein and made a part of this specification.

### BACKGROUND

### Technical Field

The invention relates to a Light-Emitting Diode (LED) chip, and particularly relates to a Micro Light-Emitting Diode (μLED) chip.

### Description of Related Art

Micro LED (μLED) has a self-luminescent display characteristic. Compared with an Organic Light Emitting Diode (OLED) display technology, which also has the self-luminous display characteristic, the μLED not only has high efficiency and a longer service life, but also a material thereof is not easily affected by environment and is relatively stable. Therefore, the μLED is expected to surpass the OLED display technology and become a mainstream of the future display technology. However, since a surface area ratio of the LED is increased under a small size and high driving current density is used, a light-emitting wavelength thereof is different due to a variation of current. Therefore, products of the μLED formed by a same manufacturing process may only be operated in small current range, which is very disadvantageous for production cost of the product.

### SUMMARY

The invention is directed to a μLED chip with at least two light-emitting regions, an epitaxial structure layer thereof includes at least two light-emitting layers of different areas, and a difference in current densities respectively passing through the at least two light-emitting regions is less than 10%, so as to effectively maintain a light-emitting wavelength and a light-emitting brightness, and achieve better light-emitting uniformity.

An embodiment of the invention provides a μLED chip having at least two light-emitting regions and including an epitaxial structure layer, a first-type electrode and at least two second-type electrodes. The epitaxial structure layer includes a first-type semiconductor layer, at least two light-emitting layers and at least two second-type semiconductor layers. The light-emitting layers are respectively located in the light-emitting regions, and one of the light-emitting layers has a first area, and the other light-emitting layer has a second area. A ratio of the first area to the second area is between 1.5 and 3, and a difference in current densities respectively passing through the at least two light-emitting regions is less than 10%. The light-emitting layers are located between the first-type semiconductor layer and the second-type semiconductor layers. The first-type electrode is electrically connected to the first-type semiconductor layer. The second-type electrodes are electrically connected to the second-type semiconductor layers, respectively.

In an embodiment of the invention, the current densities passing through the light-emitting regions are the same.

In an embodiment of the invention, the first-type electrode and the second-type electrodes are located at a same side of the epitaxial structure layer, and the first-type electrode is located between the second-type electrodes.

In an embodiment of the invention, the epitaxial structure layer has a groove. The groove penetrates through the second-type semiconductor layers, the light-emitting layers and a part of the first-type semiconductor layer, and the groove exposes a part of the first-type semiconductor layer.

In an embodiment of the invention, the first-type electrode and the second-type electrodes are located at a same side of the epitaxial structure layer, and the first-type electrode is disposed in the groove and electrically contacts the first-type semiconductor layer.

In an embodiment of the invention, a first side surface of each of the light-emitting layers relatively away from the groove is aligned with a second side surface of each of the second-type semiconductor layers relatively away from the groove. The first side surface of each of the light-emitting layers is retracted by a distance relative to an outer side surface of the first-type semiconductor layer.

In an embodiment of the invention, the μLED chip further includes an insulation layer electrically isolating the first-type electrode and the light-emitting layers and electrically isolating the first-type electrode and the second-type semiconductor layers. The insulation layer covers an inner wall of the groove, extends to the surfaces of the second-type semiconductor layers relatively away from the first-type semiconductor layer, and covers the second side surface of each of the second-type semiconductor layers, the first side surface of each of the light-emitting layers and the outer side surface of the first-type semiconductor layer.

In an embodiment of the invention, the μLED chip further includes an insulation layer. The insulation layer covers an inner wall of the groove, and extends to surfaces of the second-type semiconductor layers relatively away from the first-type semiconductor layer. The insulation layer electrically isolates the first-type electrode and the light-emitting layers, and electrically isolates the first-type electrode and the second-type semiconductor layers.

In an embodiment of the invention, the insulation layer has a plurality of openings. The openings expose a part of the second-type semiconductor layers, and the second-type electrodes are disposed in the openings and electrically contact the second-type semiconductor layers.

In an embodiment of the invention, a width of the epitaxial structure layer is decreased gradually from the first-type semiconductor layer towards the second-type semiconductor layers.

In an embodiment of the invention, the insulation layer further covers a first side surface of each of the light-emitting layers relatively away from the groove, a second side surface of each of the second-type semiconductor layers relatively away from the groove and an outer side surface of the first-type semiconductor layer.

In an embodiment of the invention, the μLED chip further includes at least two ohmic contact layers and at least two conductive reflection layers. The ohmic contact layers are disposed on the second-type semiconductor layers, and directly contact the second-type semiconductor layers. The conductive reflection layers are respectively disposed on the ohmic contact layers. The ohmic contact layers are located between the second-type semiconductor layers and the conductive reflection layers.

In an embodiment of the invention, the μLED chip further includes a groove and an insulation layer. The groove penetrates through the ohmic contact layers, the conductive reflection layers, the second-type semiconductor layers, the light-emitting layers and a part of the first-type semiconductor layer, and the groove exposes a part of the first-type semiconductor layer. The insulation layer electrically isolates the first-type electrode and the light-emitting layers and electrically isolates the first-type electrode and the second-type semiconductor layers. The insulation layer covers an inner wall of the groove, and extends to surfaces of the conductive reflection layers relatively away from the first-type semiconductor layer. The insulation layer has a plurality of openings. The openings expose a part of the conductive reflection layers, and the second-type electrodes are disposed in the openings and electrically contact the conductive reflection layers.

In an embodiment of the invention, the first-type electrode and the second-type electrodes are located at a same side of the epitaxial structure layer, and the second-type electrodes present concentric ring-shapes, and one of the second-type electrodes is located between the first-type electrode and the other one of the second-type electrodes.

In an embodiment of the invention, the epitaxial structure layer further includes a first groove and a second groove separated from each other. The first groove and the second groove penetrate through the second-type semiconductor layers, the light-emitting layers and a part of the first-type semiconductor layer, and expose a part of the first-type semiconductor layer.

In an embodiment of the invention, the first-type electrode is disposed in the first groove.

In an embodiment of the invention, the μLED chip further includes an insulation layer. The insulation layer is disposed in the first groove and the second groove, and covers an inner wall of the first groove and an inner wall of the second groove, and extends to the surfaces of the second-type semiconductor layers relatively away from the corresponding light-emitting layers. The insulation layer has a plurality of openings. The openings expose a part of the surfaces of the second-type semiconductor layers, and the second-type electrodes are disposed in the openings to electrically contact the second-type semiconductor layers. The insulation layer electrically isolates the first-type electrode and the light-emitting layers and electrically isolates the first-type electrode and the second-type semiconductor layers.

In an embodiment of the invention, a width of the epitaxial structure layer is decreased gradually from the first-type semiconductor layer towards the second-type semiconductor layers.

In an embodiment of the invention, an operation current input to the light-emitting layer with the first area is greater than an operation current input to the light-emitting layer with the second area.

In an embodiment of the invention, an area of the second-type electrode corresponding to the light-emitting layer with the first area is greater than an area of the second-type electrode corresponding to the light-emitting layer with the second area.

Based on the above description, in the design of the μLED chip of the invention, the μLED chip has at least two light-emitting regions, and the epitaxial structure layer includes at least two light-emitting layers, where the ratio of the areas of the light-emitting layers is between 1.5 and 3, and a difference in current densities passing through the at least two light-emitting regions is less than 10%. In this way, the performance of a light-emitting wavelength and brightness of the μLED chip is getting stable, so that the μLED chip has better light-emitting uniformity.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a bottom view of a μLED chip according to an embodiment of the invention.

FIG. 1B is a cross-sectional view of FIG. 1A along a line A-A′.

FIG. 1C is a cross-sectional view of FIG. 1A along a line B-B′.

FIG. 2 is a cross-sectional view of a μLED chip according to another embodiment of the invention.

FIG. 3 is a cross-sectional view of a μLED chip according to another embodiment of the invention.

FIG. 4A is a bottom view of a μLED chip according to another embodiment of the invention.

FIG. 4B is a cross-sectional view of FIG. 4A along a line C-C′.

FIG. 5A is a bottom view of a μLED chip according to another embodiment of the invention.

FIG. 5B is a cross-sectional view of FIG. 5A along a line D-D′.

FIG. 6 is a bottom view of a μLED chip according to another embodiment of the invention.

### DESCRIPTION OF THE EMBODIMENTS

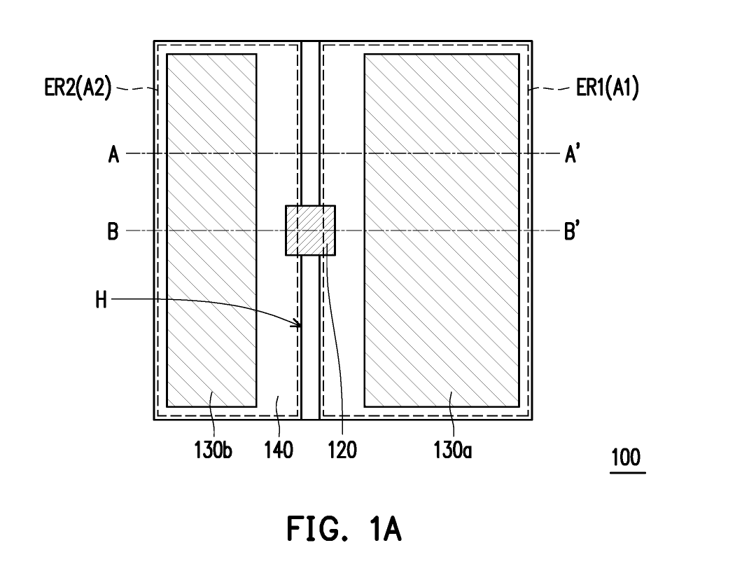

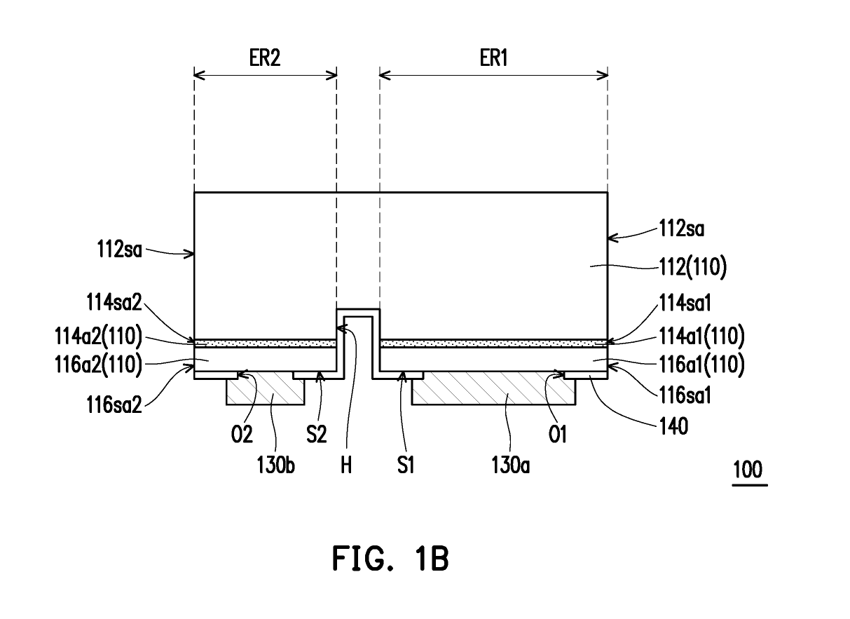

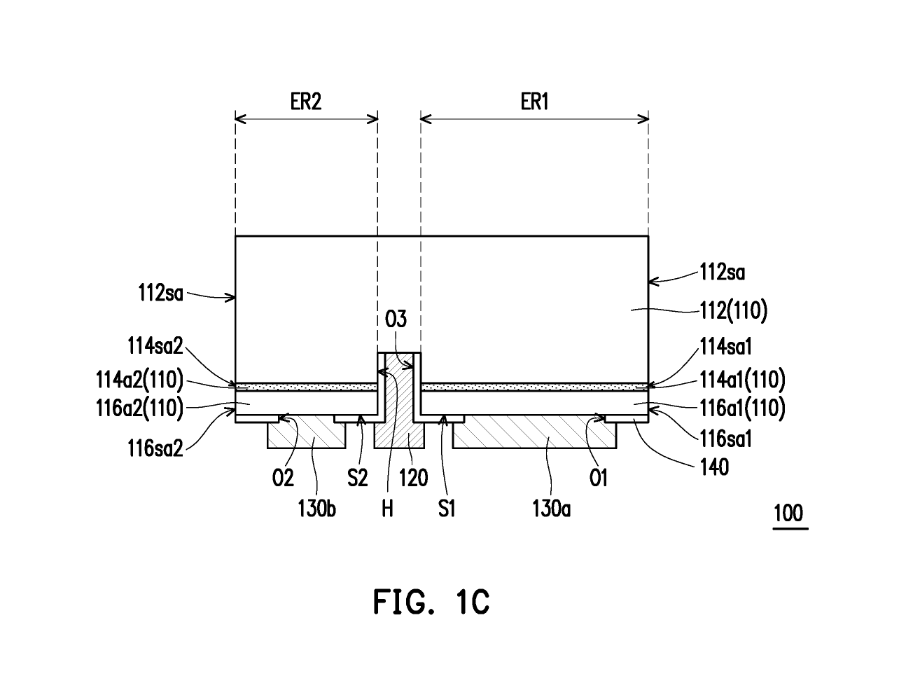

FIG. 1A is a bottom view of a μLED chip according to an embodiment of the invention. FIG. 1B is a cross-sectional view of FIG. 1A along a line A-A′. FIG. 1C is a cross-sectional view of FIG. 1A along a line B-B′.

Referring to FIG. 1A, FIG. 1B and FIG. 1C, in the embodiment, the μLED chip 100 has at least two light-emitting regions (two light-emitting regions ER1, ER2 are schematically illustrated in FIG. 1A). The μLED chip 100 includes an epitaxial structure layer 110, a first-type electrode 120 and at least two second-type electrodes (two second-type electrodes 130a and 130b are schematically illustrated in FIG. 1A). The epitaxial structure layer 110 includes a first-type semiconductor layer 112, at least two light-emitting layers (two light-emitting layers 114a1, 114a2 are schematically illustrated in FIG. 1B and FIG. 1C) and at least two second-type semiconductor layers (two second-type semiconductor layers 116a1, 116a2 are schematically illustrated in FIG. 1B and FIG. 1C).

In detail, the light-emitting layers 114a1 and 114a2 are respectively located in the light-emitting regions ER1 and ER2, where the light-emitting layers 114a1 and 114a2 may be independently controlled to emit light. The light-emitting layers 114a1 and 114a2 are located between the first-type semiconductor layer 112 and the second-type semiconductor layer 116a1 and 116a2. The first-type electrode 120 electrically contact the first-type semiconductor layer 112, and the second-type electrodes 130a and 130b respectively and electrically contact the second-type semiconductor layers 116a1 and 116a2. Particularly, the light-emitting layer 114a1 of the embodiment has a first area A1, and the light-emitting layer 114a2 has a second area A2. The first area A1 is greater than the second area A2, and a ratio of the first area A1 and the second area A2 is, for example, between 1.5 and 3. Preferably, a difference in current densities respectively passing through the light-emitting regions ER1 and ER2 is less than 10%. In the embodiment, the light-emitting region ER1 is equal to the first area A1 of the light-emitting layer 114a1, and the light-emitting region ER2 is equal to the second area A2 of the light-emitting layer 114a2. In an embodiment, current densities respectively passing through the light-emitting regions ER1 and ER2 are the same.

On the other hand, since the first area A1 is greater than the second area A2, an operation current input to the light-emitting layer 114a1 with the first area A1 is greater than an operation current input to the light-emitting layer 114a2 with the second area A2. Namely, in the embodiment, the input currents are proportional to the areas of the light-emitting layers 114a1 and 114a2. Moreover, as shown in FIG. 1A, in view of the bottom view, the first-type electrode 120 and the second-type electrodes 130a and 130b of the embodiment are located at a same side of the epitaxial structure layer 110, and the first-type electrode 120 is located between the second-type electrodes 130a and 130b, and an area of the first-type electrode 120 is smaller than an area of the second-type electrodes 130a and 130b. Preferably, an area of the second-type electrode 130a corresponding to the light-emitting layer 114a1 with the first area A1 is greater than an area of the second-type electrode 130b corresponding to the light-emitting layer 114a2 with the second area A2. Namely, in the embodiment, the areas of the second-type electrodes 130a and 130b are proportional to the areas of the light-emitting layers 114a1 and 114a2.

Herein, the first-type semiconductor layer 112 is one of a P-type doped semiconductor layer and an N-type doped semiconductor layer, and the second-type semiconductor layers 116a1 and 116a2 are respectively the other one of the P-type doped semiconductor layer and the N-type doped semiconductor layer. To be specific, the first-type semiconductor layer 112 is, for example, the N-type doped semiconductor layer, and the second-type semiconductor layers 116a1 and 116a2 are, for example, respectively the P-type doped semiconductor layer, but the invention is not limited thereto. A material of the N-type doped semiconductor layer is, for example, an n-GaN, and a material of the P-type doped semiconductor layer is, for example, a p-GaN, but the invention is not limited thereto. On the other hand, a structure of the light-emitting layers 114a1 and 114a2 are, for example, a Multiple Quantum Well (MQW) structure. The MQW structure includes a plurality of quantum wells and a plurality of quantum barriers alternately arranged in a repeated manner. Further, a material of the light-emitting layers 114a1 and 114a2, for example, includes alternately stacked multilayer InGaN and multilayer GaN, and by designing a ratio of indium or gallium in the light-emitting layers 114a1 and 114a2, the light-emitting layers 114a1 and 114a2 may emit light of different wavelength ranges. It should be noted that the aforementioned material of the light-emitting layers 114a1 and 114a2 is only an example, and the material of the light-emitting layers 114a1 and 114a2 is not limited to InGaN and GaN.

Moreover, referring to FIG. 1A and FIG. 1C, the epitaxial structure layer 110 has a groove H, where the groove H penetrates through the second-type semiconductor layers 116a1 and 116a2, the light-emitting layers 114a1 and 114a2 and a part of the first-type semiconductor layer 112, and the groove H exposes a part of the first-type semiconductor layer 112. The first-type electrode 120 and the second-type electrodes 130a and 130b are located at a same side of the epitaxial structure layer 110, and the first-type electrode 120 is disposed in the groove H and electrically contacts the first-type semiconductor layer 112. Herein, the μLED chip 100 is embodied by a horizontal type μLED, where an outer side surface 112sa of the first-type semiconductor layer 112 is aligned with first side surfaces 114sa1 and 114sa2 of the light-emitting layers 114a1 and 114a2 relatively away from the groove H and the second side surfaces 116sa1 and 116sa2 of the second-type semiconductor layers 116a1 and 116a2 relatively away from the groove H. In other words, the first side surfaces 114sa1 of the light-emitting layers 114a1, the second side surfaces 116sa1 of the second-type semiconductor layers 116a1 and the outer side surface 112sa are formed as a continue surface. The first side surfaces 114sa2 of the light-emitting layers 114a2, the second side surfaces 116sa2 of the second-type semiconductor layers 116a2 and the outer side surface 112sa are formed as a continue surface.

Moreover, the μLED chip 100 of the embodiment further includes an insulation layer 140, where the insulation layer 140 covers an inner wall of the groove H, and extends to surface S1 of the second-type semiconductor layer 116a1 and surface S2 of the second-type semiconductor layer 116a2 relatively away from the first-type semiconductor layer 112. The insulation layer 140 electrically isolates the first-type electrode 120 and the light-emitting layers 114a1 and 114a2 and electrically isolates the first-type electrode 120 and the second-type semiconductor layers 116a1 and 116a2, so as to avoid short-circuit. In other embodiments that are not shown, the groove may be not configured with the insulation layer or filled with a cushioning material, which is still considered to be within a projection range of the invention. The groove H is, for example, formed by an etching process, and is, for example, formed by an Inductively-Coupled Plasma (ICP) process, which is not limited by the invention. Further, the insulation layer 140 of the embodiment has a plurality of openings O1, O2 and O3, where the openings O1 and O2 expose a part of the second-type semiconductor layers 116a1 and 116a2, and the second-type electrodes 130a and 130b are disposed in the openings O1 and O2 and electrically contact the second-type semiconductor layers 116a1 and 116a2. To be specific, the opening O3 is located in the groove H and exposes a part of the first-type semiconductor layer 112, and the first-type electrode 120 is disposed in the opening O3 and electrically contacts the first-type semiconductor layer 112. Herein, a material of the insulation layer 140 is, for example, Benzocyclobutene (BCB) or Silicon Dioxide (SiO₂), but is not limited thereto.

In brief, the μLED chip 100 of the embodiment has the light-emitting regions ER1 and ER2, and an area ratio of the light-emitting layers 114a1 and 114a2 is between 1.5 and 3. A user may select a proper light-emitting region to emit light according to an operation current range, so as to maintain a similar current density, and accordingly ameliorate light-emitting uniformity. Namely, a difference in current densities respectively passing through the light-emitting regions ER1 and ER2 is less than 10%. In this way, a light-emitting wavelength and a light-emitting brightness of the μLED chip 100 are maintained constant, and better light-emitting uniformity of the μLED chip 100 is achieved. Moreover, if the light emitted by the light-emitting layer 114a1 is not bright enough, the light-emitting layer 114a2 may perform brightness compensation, such that the μLED chip 100 of the invention may stall maintains a better brightness performance.

It should be noted that reference numbers of the components and a part of contents of the aforementioned embodiment are also used in the following embodiment, wherein the same reference numbers denote the same or like components, and descriptions of the same technical contents are omitted. The aforementioned embodiment may be referred for descriptions of the omitted parts, and detailed descriptions thereof are not repeated in the following embodiment.

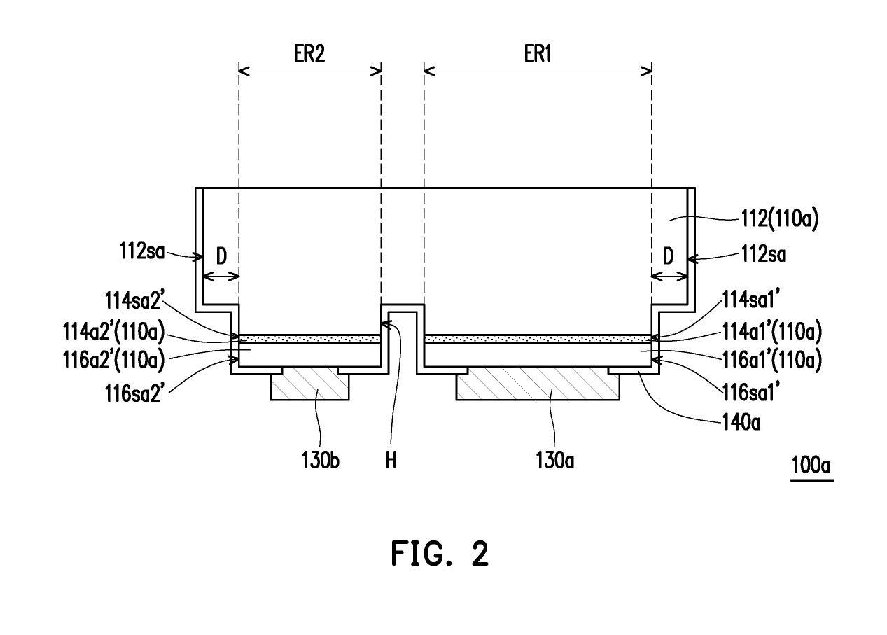

FIG. 2 is a cross-sectional view of a μLED chip according to another embodiment of the invention. Referring to FIG. 1B and FIG. 2, the μLED chip 100a of the embodiment is similar to the μLED chip 100 of FIG. 1B, and differences there between are that the first side surfaces 114sa1′ and 114sa2′ of the light-emitting layers 114a1′ and 114a2′ of the epitaxial structure layer 110a relatively away from the groove H are aligned with the second side surfaces 116sa1′ and 116sa2′ of the second-type semiconductor layers 116a1′ and 116a2′ relatively away from the groove H, and the first side surfaces 114sa1′ and 114sa2′ of the light-emitting layers 114a1′ and 114a2′ are retracted by a distance D relative to an outer side surface 112sa of the first-type semiconductor layer 112. Moreover, the insulation layer 140a of the embodiment further covers the second side surfaces 116sa1′ and 116sa2′ of the second-type semiconductor layers 116a1′ and 116a2′, the first side surfaces 114sa1′ and 114sa2′ of the light-emitting layers 114a1′ and 114a2′ and the outer side surface 112sa of the first-type semiconductor layer 112.

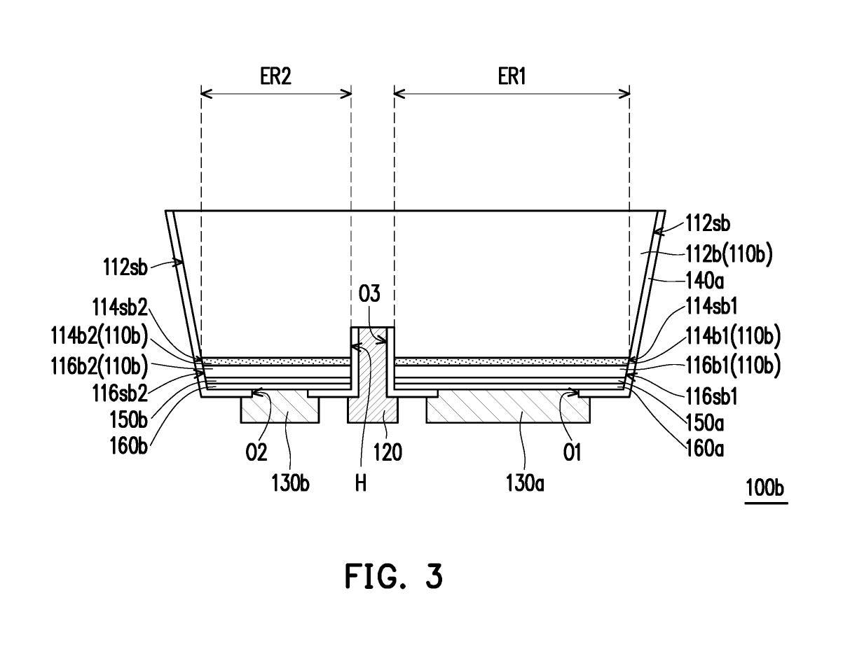

FIG. 3 is a cross-sectional view of a μLED chip according to another embodiment of the invention. Referring to FIG. 2 and FIG. 3, the μLED chip 100b of the embodiment is similar to the μLED chip 100a of FIG. 2, and differences there between are that a total width of the epitaxial structure layer 110b in a cross-section is decreased gradually from the first-type semiconductor layer 112b towards the second-type semiconductor layers 116b1 and 116b2. Namely, a cross-sectional shape of the epitaxial structure layer 110b is embodied by an inverted trapezoid. The insulation layer 140 covers the outer side surface 112sb of the first-type semiconductor layer 112b, the second side surface 116sb1 of the second-type semiconductor layer 116b1, the second side surface 116sb2 of the second-type semiconductor layer 116b2, the first side surface 114sb1 of the light-emitting layer 114b1 and the first side surface 114sb2 of the light-emitting layer 114b2.

Moreover, the μLED chip 100b of the embodiment further includes at least two ohmic contact layers (two ohmic contact layers 150a and 150b are schematically illustrated in FIG. 3) and at least two conductive reflection layers (two conductive reflection layers 160a and 160b are schematically illustrated in FIG. 3). The ohmic contact layers 150a and 150b are disposed respectively on the second-type semiconductor layers 116b1 and 116b2, and directly contact the second-type semiconductor layers 116b1 and 116b2. The conductive reflection layers 160a and 160b are disposed respectively on the ohmic contact layers 150a and 150b. The ohmic contact layers 150a and 150b are located between the second-type semiconductor layers 116b1 and 116b2 and the conductive reflection layers 160a and 160b. In other words, the ohmic contact layers 150a and 150b and the conductive reflection layers 160a and 160b are not in direct contact with the light-emitting layers 114b1 and 114b2 and the first-type semiconductor layer 112b.

Since an area of the μLED chip 100b is relatively small, injection efficiency and a current distribution of electron holes may be improved through the ohmic contact layers 150a and 150b formed on the second-type semiconductor layers 116b1 and 116b2. Moreover, the openings O1 and O2 of the insulation layer 140a of the embodiment expose a part of the conductive reflection layers 160a and 160b, where the second-type electrodes 130a and 130b are respectively disposed in the openings O1 and O2 to electrically contact the conductive reflection layers 160a and 160b. In other words, the conductive reflection layers 160a and 160b of the embodiment are located between the second-type electrodes 130a and 130b and the ohmic contact layers 150a and 150b, which avails improving the light-emitting efficiency of the μLED chip 100b and protecting the ohmic contact layers 150a and 150b.

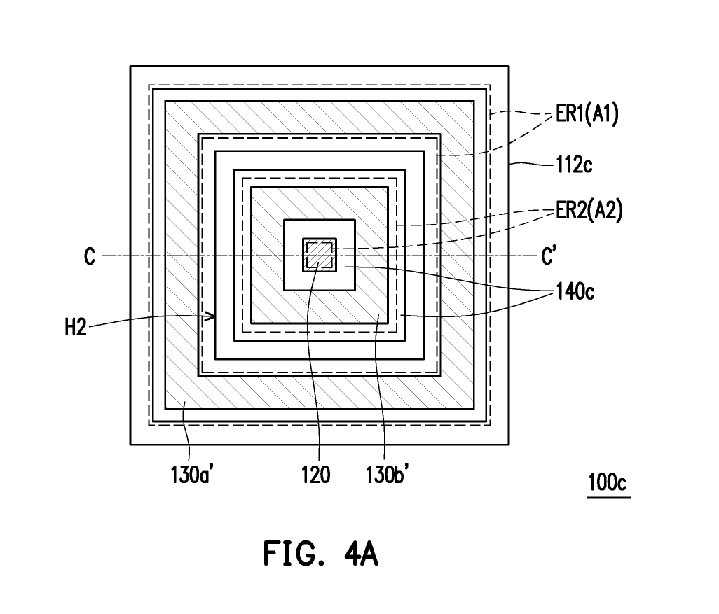

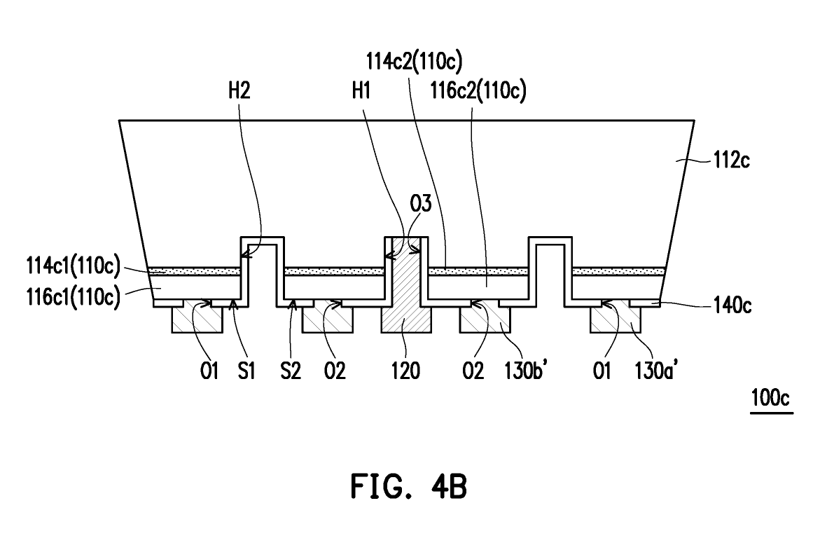

FIG. 4A is a bottom view of a μLED chip according to another embodiment of the invention. FIG. 4B is a cross-sectional view of FIG. 4A along a line C-C′. Referring to FIG. 3, FIG. 4A and FIG. 4B, the μLED chip 100c of the embodiment is similar to the μLED chip 100b of FIG. 3, and differences there between are that in view of the bottom view, the second-type electrodes 130a′, 130b′ present concentric ring-shapes, and the second-type electrode 130b′ is located between the first-type electrode 120 and another second-type electrode 130a′. Namely, the second-type electrodes 130a′, 130b′ of the embodiment are concentrically configured to make an effectively use of area. The light-emitting layers 114c1 and 114c2 also present concentric ring-shapes, and the second-type semiconductor layers 116c1 and 116c2 also present concentric ring-shapes. The light-emitting layer 114c2 is located between the first-type electrode 120 and the light-emitting layer 114c1, and the second-type semiconductor layer 116c2 is located between the first-type electrode 120 and the second-type semiconductor layer 116c1.

Further, in the embodiment, the epitaxial structure layer 110c further includes a first groove H1 and a second groove H2 separated from each other. The first groove H1 and the second groove H2 penetrate through the second-type semiconductor layers 116c1 and 116c2, the light-emitting layers 114c1 and 114c2 and a part of the first-type semiconductor layer 112c, and expose a part of the first-type semiconductor layer 112c. The first-type electrode 120 and the second-type electrodes 130a′ and 130b′ are located at a same side of the epitaxial structure layer 110c, and the first-type electrode 120 is disposed in the first groove H1. The insulation layer 140c is disposed in the first groove H1 and the second groove H2, and covers an inner wall of the first groove H1 and an inner wall of the second groove H2, and extends to surfaces S1 and S2 of the second-type semiconductor layers 116c1 and 116c2 relatively away from the corresponding light-emitting layers 114c1 and 114c2. The openings O1 and O2 of the insulation layer 140c expose a part of the surfaces S1 and S2 of the second-type semiconductor layers 116c1 and 116c2, and the second-type electrodes 130a′ and 130b′ are respectively disposed in the openings O1 and O2 to electrically contact the second-type semiconductor layers 116c1 and 116c2, respectively. The insulation layer 140c electrically isolates the first-type electrode 120 and the at least two light-emitting layers 114c1 and 114c2 and electrically isolates the first-type electrode 120 and the at least two second-type semiconductor layers 116c1 and 116c2.

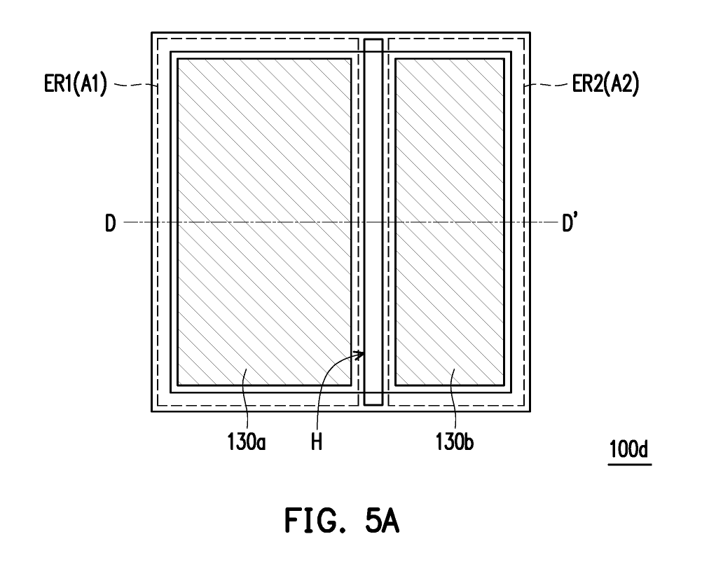

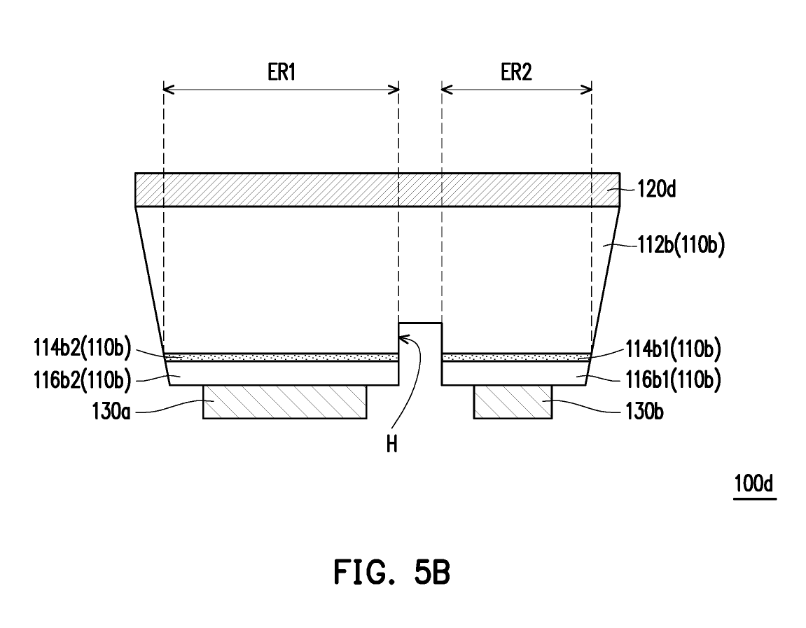

FIG. 5A is a bottom view of a μLED chip according to another embodiment of the invention. FIG. 5B is a cross-sectional view of FIG. 5A along a line D-D′. Referring to FIG. 3, FIG. 5A and FIG. 5B, the μLED chip 100d of the embodiment is similar to the μLED chip 100b of FIG. 3, and a difference there between is that the first-type electrode 120d and the second-type electrodes 130a and 130b of the μLED chip 100d of the embodiment are located at two opposite sides of the epitaxial structure layer 110b. The first-type semiconductor layer 112b of the epitaxial structure layer 110b is located between the first-type electrode 120d and the light-emitting layers 114b1 and 114b2. In the embodiment, the μLED chip 100d is not configured with the insulation layer. In other embodiments that are not shown, the groove H may also be filled with an insulation material or a cushioning material, which is still considered to be within the protection range of the invention. The μLED chip 100d is embodied by a vertical type μLED.

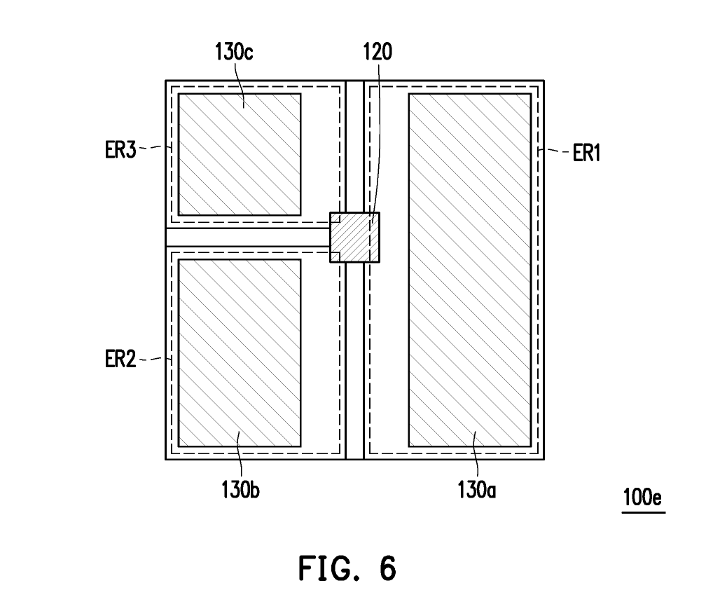

FIG. 6 is a bottom view of a μLED chip according to another embodiment of the invention. Referring to FIG. 1 and FIG. 6, the μLED chip 100e of the embodiment is similar to the μLED chip 100 of FIG. 1, and a difference there between is that the μLED chip 100e of the embodiment has three light-emitting regions ER1, ER2 and ER3 and three second-type electrodes 130a, 130b and 130c, where areas of the three light-emitting regions ER1, ER2 and ER3 are different, and areas of the three second-type electrodes 130a, 130b and 130c are also different, but the invention is not limited thereto. In other embodiments that are not shown, the light-emitting regions of the μLED chip may have a same area, or a part of the light-emitting regions have the same area, which is still considered to be within the protection range of the invention. Moreover, the invention does not limit the areas of the second-type electrodes 130a, 130b and 130c, and as long as the areas of the second-type electrodes 130a, 130b and 130c are proportional to the areas of the corresponding light-emitting layers, it is considered to be within the protection range of the invention.

In summary, in the design of the μLED chip of the invention, the μLED chip has at least two light-emitting regions, and the epitaxial structure layer includes at least two light-emitting layers, where the ratio of the areas of the light-emitting layers is between 1.5 and 3, and a difference in current densities passing through the at least two light-emitting regions is less than 10%. In this way, a light-emitting wavelength and brightness of the μLED chip is maintained constant, so that the μLED chip has better light-emitting uniformity. Therefore, a light-emitting region of a corresponding area may be driven according to an operation current range, so that one μLED chip may be applied to different operation currents to maintain current density for driving light emitting. Moreover, if the light emitted by one light-emitting layer is not bright enough, the other light-emitting layer may perform brightness compensation, such that the μLED chip of the invention may stall maintains a better brightness performance.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. A micro light-emitting diode chip having at least two light-emitting regions and comprising:
an epitaxial structure layer, comprising:
a first-type semiconductor layer;
at least two light-emitting layers, respectively located in the at least two light-emitting regions, and one of the light-emitting layers has a first area, and the other light-emitting layer has a second area, a ratio of the first area to the second area is between 1.5 and 3, and a difference in current densities respectively passing through the at least two light-emitting regions is less than 10%; and
at least two second-type semiconductor layers, wherein the at least two light-emitting layers are located between the first-type semiconductor layer and the at least two second-type semiconductor layers;
a first-type electrode, electrically connected to the first-type semiconductor layer; and
at least two second-type electrodes, electrically connected to the at least two second-type semiconductor layers, respectively.

2. The micro light-emitting diode chip as claimed in claim 1, wherein the current densities passing through the at least two light-emitting regions are the same.

3. The micro light-emitting diode chip as claimed in claim 1, wherein the first-type electrode and the at least two second-type electrodes are located at a same side of the epitaxial structure layer, and the first-type electrode is located between the at least two second-type electrodes.

4. The micro light-emitting diode chip as claimed in claim 1, wherein the epitaxial structure layer has a groove penetrating through the at least two second-type semiconductor layers, the at least two light-emitting layers and a part of the first-type semiconductor layer, and the groove exposes a part of the first-type semiconductor layer.

5. The micro light-emitting diode chip as claimed in claim 4, wherein the first-type electrode and the at least two second-type electrodes are located at a same side of the epitaxial structure layer, and the first-type electrode is disposed in the groove and electrically contacts the first-type semiconductor layer.

6. The micro light-emitting diode chip as claimed in claim 5, wherein a first side surface of each of the light-emitting layers relatively away from the groove is aligned with a second side surface of each of the second-type semiconductor layers relatively away from the groove, and the first side surface of each of the light-emitting layers is retracted by a distance relative to an outer side surface of the first-type semiconductor layer.

7. The micro light-emitting diode chip as claimed in claim 6, further comprising:
an insulation layer, electrically isolating the first-type electrode and the at least two light-emitting layers and electrically isolating the first-type electrode and the at least two second-type semiconductor layers, wherein the insulation layer covers an inner wall of the groove, extends to the surfaces of the at least two second-type semiconductor layers relatively away from the first-type semiconductor layer, and covers the second side surface of each of the second-type semiconductor layers, the first side surface of each of the light-emitting layers and the outer side surface of the first-type semiconductor layer.

8. The micro light-emitting diode chip as claimed in claim 5, further comprising:
an insulation layer, covering an inner wall of the groove, and extending to surfaces of the at least two second-type semiconductor layers relatively away from the first-type semiconductor layer, wherein the insulation layer electrically isolates the first-type electrode and the at least two light-emitting layers, and electrically isolates the first-type electrode and the at least two second-type semiconductor layers.

9. The micro light-emitting diode chip as claimed in claim 8, wherein the insulation layer has a plurality of openings exposing a part of the at least two second-type semiconductor layers, and the at least two second-type electrodes are disposed in the openings and electrically contact the at least two second-type semiconductor layers.

10. The micro light-emitting diode chip as claimed in claim 8, wherein a width of the epitaxial structure layer is decreased gradually from the first-type semiconductor layer towards the at least two second-type semiconductor layers.

11. The micro light-emitting diode chip as claimed in claim 10, wherein the insulation layer further covers a first side surface of each of the light-emitting layers relatively away from the groove, a second side surface of each of the second-type semiconductor layers relatively away from the groove and an outer side surface of the first-type semiconductor layer.

12. The micro light-emitting diode chip as claimed in claim 1, further comprising:
at least two ohmic contact layers, disposed on the at least two second-type semiconductor layers, and directly contacting the at least two second-type semiconductor layers; and
at least two conductive reflection layers, respectively disposed on the at least two ohmic contact layers, wherein the at least two ohmic contact layers are located between the at least two second-type semiconductor layers and the at least two conductive reflection layers.

13. The micro light-emitting diode chip as claimed in claim 12, further comprising:
a groove, penetrating through the at least two ohmic contact layers, the at least two conductive reflection layers, the at least two second-type semiconductor layers, the at least two light-emitting layers and a part of the first-type semiconductor layer, wherein the groove exposes a part of the first-type semiconductor layer; and
an insulation layer, electrically isolating the first-type electrode and the at least two light-emitting layers and electrically isolating the first-type electrode and the at least two second-type semiconductor layers, wherein the insulation layer covers an inner wall of the groove, and extends to surfaces of the at least two conductive reflection layers relatively away from the first-type semiconductor layer, wherein the insulation layer has a plurality of openings exposing a part of the at least two conductive reflection layers, and the at least two second-type electrodes are disposed in the openings and electrically contact the at least two conductive reflection layers.

14. The micro light-emitting diode chip as claimed in claim 1, wherein the first-type electrode and the at least two second-type electrodes are located at a same side of the epitaxial structure layer, and the at least two second-type electrodes present concentric ring-shapes, and one of the second-type electrodes is located between the first-type electrode and the other one of the second-type electrodes.

15. The micro light-emitting diode chip as claimed in claim 14, wherein the epitaxial structure layer further comprises a first groove and a second groove separated from each other, the first groove and the second groove penetrate through the at least two second-type semiconductor layers, the at least two light-emitting layers and a part of the first-type semiconductor layer, and expose a part of the first-type semiconductor layer.

16. The micro light-emitting diode chip as claimed in claim 15, wherein the first-type electrode is disposed in the first groove.

17. The micro light-emitting diode chip as claimed in claim 16, further comprising:
an insulation layer, disposed in the first groove and the second groove, and covering an inner wall of the first groove and an inner wall of the second groove, and extending to surfaces of the at least two second-type semiconductor layers relatively away from the corresponding light-emitting layers, wherein the insulation layer has a plurality of openings exposing a part of the surfaces of the at least two second-type semiconductor layers, and the at least two second-type electrodes are disposed in the openings to electrically contact the at least two second-type semiconductor layers, and the insulation layer electrically isolates the first-type electrode and the at least two light-emitting layers and electrically isolates the first-type electrode and the at least two second-type semiconductor layers.

18. The micro light-emitting diode chip as claimed in claim 15, wherein a width of the epitaxial structure layer is decreased gradually from the first-type semiconductor layer towards the at least two second-type semiconductor layers.

19. The micro light-emitting diode chip as claimed in claim 1, wherein an operation current input to the light-emitting layer with the first area is greater than an operation current input to the light-emitting layer with the second area.

20. The micro light-emitting diode chip as claimed in claim 1, wherein an area of the second-type electrode corresponding to the light-emitting layer with the first area is greater than an area of the second-type electrode corresponding to the light-emitting layer with the second area.
